(19) United States
(12) Patent Application Publication
(10) Pub. No.: US 2018/0374736 A1
(43) Pub. Date: Dec. 27, 2018

(54) ELECTROSTATIC CARRIER FOR DIE BONDING APPLICATIONS

(71) Applicant: Applied Materials, Inc., Santa Clara, CA (US)

(72) Inventors: Niranjan KUMAR, Santa Clara, CA (US); Kim Ramkumar VELLORE, San Jose, CA (US); Douglas H. BURNS, Saratoga, CA (US); Gautam PISHARODY, Newark, CA (US); Seshadri RAMASWAMI, Saratoga, CA (US); Douglas A. BUCHBERGER, JR., Livermore, CA (US)

(21) Appl. No.: 16/008,569

(22) Filed: Jun. 14, 2018

Related U.S. Application Data
(60) Provisional application No. 62/523,600, filed on Jun. 22, 2017.

(51) Int. Cl. H01L 21/683; H01L 21/02; H01L 21/67

(52) U.S. Cl. CPC H01L 21/6833; H01L 21/6836; H01L 21/6704; H01L 21/02057

(57) ABSTRACT

Embodiments of the disclosure relate to the use of an electrostatic carrier for securing, transporting and assembling dies on a substrate. In one embodiment, an electrostatic carrier includes a body having a top surface and a bottom surface, at least a first bipolar chucking electrode disposed within the body, at least two contact pads disposed on the bottom surface of the body and connected to the first bipolar chucking electrode, and a floating electrode disposed between the first bipolar chucking electrode and the bottom surface. In another embodiment, a die-assembling system includes the electrostatic carrier configured to electrostatically secure a plurality of dies, a carrier-holding platform configured to hold the electrostatic carrier, a die input platform and a loading robot having a range of motion configured to pick the plurality of dies from the die input platform and place them on the electrostatic carrier.

### CROSS-REFERENCE TO RELATED APPLICATIONS

This application claims benefit of U.S. Provisional Application Ser. No. 62/523,600, filed Jun. 22, 2017 (Attorney Docket No. APPM/25240USL), of which is incorporated by reference in its entirety.

### BACKGROUND

### Field

Embodiments of the present disclosure generally relate to an apparatus, system and method for securing, transporting and assembling dies on a substrate. More specifically, the embodiments described herein relate to the use of an electrostatic carrier for securing, transporting and assembling dies on a substrate.

### Description of the Related Art

During the semiconductor manufacturing process, prepared dies are cleaned prior to assembly on a substrate, such as a CMOS wafer. The prepared dies are attached by an adhesive on a tape frame during cleaning operations. After cleaning, the dies from a tape frame are transferred to the CMOS wafer individually, since the dies need to be aligned on the substrate. The individual transfer and positioning of dies on the substrate is time-consuming and limits the throughput of the manufacturing process significantly.

Thus, there is a need for an improved way of securing, transporting and assembling dies in bulk onto a substrate.

### SUMMARY

Embodiments of the disclosure generally relate to the use of an electrostatic carrier for securing, transporting and assembling dies on a substrate. In one embodiment of the disclosure, the electrostatic carrier includes a body having a top surface and a bottom surface, at least a first bipolar chucking electrode disposed within the body, at least two contact pads disposed on the bottom surface of the body and connected to the first bipolar chucking electrode, and a floating electrode disposed between the first bipolar chucking electrode and the bottom surface.

In another embodiment of the disclosure, a die-assembling system is disclosed. The die-assembling system includes an electrostatic carrier configured to electrostatically secure a plurality of dies, a carrier-holding platform configured to hold the electrostatic carrier, a die input platform and a loading robot having a range of motion configured to pick the plurality of dies from the die input platform and place them on the electrostatic carrier. The electrostatic carrier includes a body having a top surface and a bottom surface, at least a first bipolar chucking electrode disposed within the body, at least two contact pads disposed on the bottom surface of the body and connected to the first bipolar chucking electrode, and a floating electrode disposed between the first bipolar chucking electrode and the bottom surface.

Yet another embodiment provides a method of assembling a plurality of dies on a substrate. The method includes placing the plurality of dies from a die input platform on to an electrostatic carrier, electrostatically chucking the plurality of dies to the electrostatic carrier, moving the electrostatic carrier to a carrier-holding platform of a die-assembling system, applying a liquid on the plurality of dies, moving a substrate to engage with the plurality of dies, and de-chucking the plurality of dies from the electrostatic carrier.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a simplified front cross-sectional view of an electrostatic carrier for die-bonding applications.

FIG. 2 is a top view of a first embodiment of the electrostatic carrier of FIG. 1.

FIG. 3 is a top view of a second embodiment of the electrostatic carrier of FIG. 1.

FIG. 4 is a top view of a third embodiment of the electrostatic carrier of FIG. 1.

FIG. 5 is a top view of a fourth embodiment of the electrostatic carrier of FIG. 1.

FIG. 6 is an electrical schematic view of the electrostatic carrier of FIG. 1.

FIG. 7 is a simplified front cross-sectional view of a die-assembling system for loading a plurality of dies on the electrostatic carrier of FIG. 1.

FIG. 8 is a simplified front cross-sectional view of a die-assembling system for assembling a plurality of dies from the electrostatic carrier of FIG. 1 on to a substrate.

FIGS. 9A-9C show three stages of assembling dies to a substrate using the electrostatic carrier of FIG. 1.

FIG. 10 shows a block diagram of a method of assembling a plurality of dies on a substrate using the electrostatic carrier of FIG. 1.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure generally relate to the use of an electrostatic carrier for securing, transporting and assembling dies on a substrate. The electrostatic carrier described herein is used to electrostatically secure a plurality of dies from a tape frame or other die source. The electrostatic carrier is used to transport the plurality of dies thus secured through cleaning operations and to a die-assembling system, where the plurality of dies is assembled on a substrate.

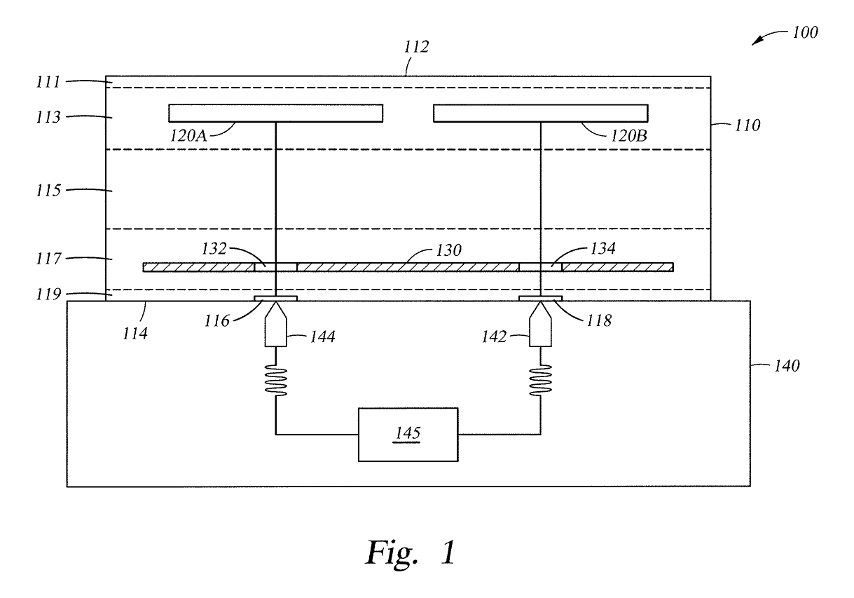

Referring to FIG. 1, the electrostatic carrier 100 includes a body 110 having a top surface 112 and a bottom surface 114. In the illustrative example of FIG. 1, the body 110 is cylindrical in shape but may have any suitable shape. In the embodiments where the body 110 is disk-shaped, the body 110 may have a diameter substantially similar to a 200 mm substrate, a 300 mm substrate or a 450 mm substrate. The top surface 112 of the body 110 substantially matches the shape and size of a substrate to be disposed thereon. The bottom surface 114 of the body 110 includes two contact pads 116 and 118.

The body 110 is fabricated from one or more layers of dielectric material vertically stacked on each other. In some embodiments, the body 110 has five layers, as shown in FIG. 1. A top layer 111 and a bottom layer 119 are made of a coating material, such as but not limited to a hydrophobic material which could withstand plasma conditions and a cleaning operation. The hydrophobic material helps prevent a cleaning liquid from seeping through the edges of the chucked assembly comprising the plurality of dies chucked to the electrostatic carrier 100. If the cleaning liquid seeps into the region between the plurality of dies and the electrostatic carrier 100 by capillary effect, the plurality of dies can become undesirably de-chucked from the electrostatic carrier 100 during the cleaning operation.

A middle layer 115 comprises the core of the electrostatic carrier 100. The core is the structural layer of the electrostatic carrier 100 contributing to its rigidity. The core may be made of a dielectric material to avoid electrical arcing issues, such as but not limited to ceramic, resin, glass, and polyimide materials as discussed above. In some embodiments, the core may also be made of a silicon wafer with oxide coating.

A layer 113 between the middle layer 115 and the top layer 111 as well as the a layer 117 between the middle layer 115 and the bottom layer 119 are also made of a dielectric material, such as but not limited to a ceramic or polyimide material. Suitable examples of the ceramic materials include silicon oxide, such as quartz or glass, sapphire, aluminum oxide (Al₂O₃), aluminum nitride (AlN), yttrium containing materials, yttrium oxide (Y₂O₃), yttrium-aluminum-garnet (YAG), titanium oxide (TiO), titanium nitride (TiN), silicon carbide (SiC) and the like. The 113 as well as the layer 117 may also comprise laminated or spin-on polymeric or inorganic film such as silicon nitride. A bipolar electrostatic chucking electrode 120 is disposed in the layer 113.

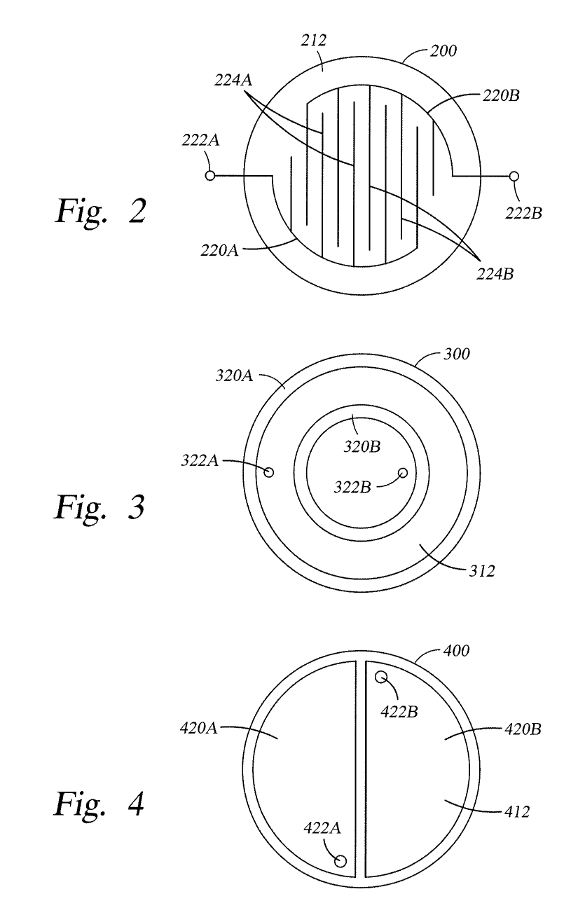

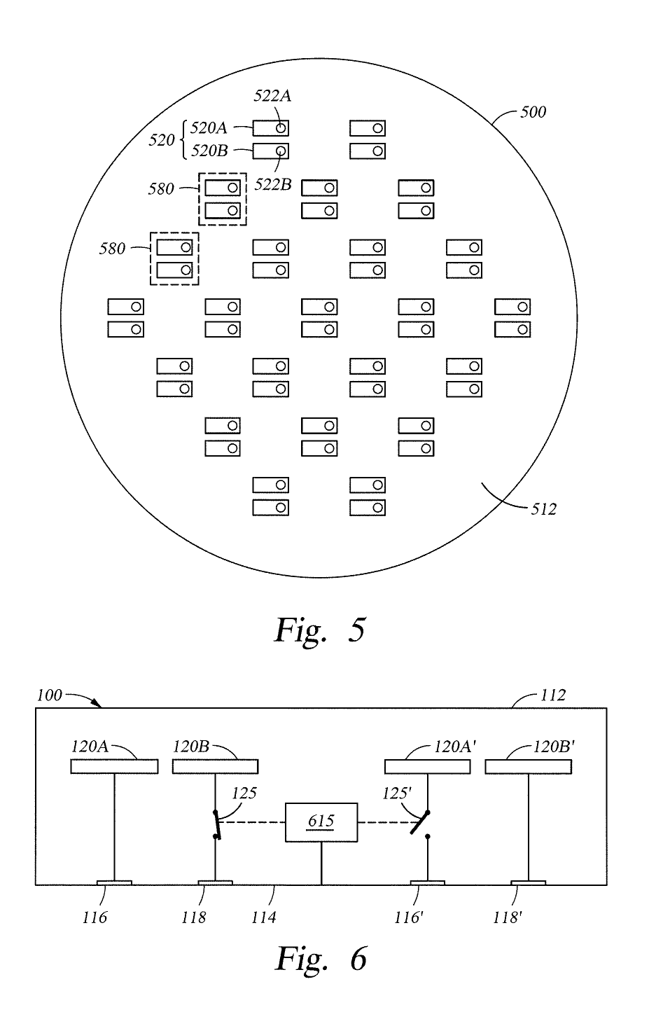

The bipolar electrostatic chucking electrode 120 disposed in the layer 113 includes two electrodes 120A and 120B. The electrode 120A is electrically connected to the contact pad 116. The electrode 120B is electrically connected to the contact pad 118. The electrodes 120A, 120B may be charged with opposite polarities as needed when a voltage power is applied thereto, thus generating an electrostatic force. The electrodes 120A, 120B are made from a conductive material, such as but not limited to, tungsten, copper, silver, silicon, platinum. The electrodes 120A, 120B are fabricated with electroplating, screen print, etc. The electrodes 120A, 120B may be configured in any manner necessary to electrostatically retain a plurality of dies. For example, the electrodes 120A, 120B may be concentric (as shown in FIG. 3), semi-circular (as shown in FIG. 4), or interdigitated (as shown in FIGS. 2 and 5).

A floating electrode 130 is disposed in the layer 117 between the bipolar electrostatic chucking electrode 120 and the bottom surface 114 of the body 110. The floating electrode 130 substantially prevents electrostatic charges from accumulating on the bottom surface 114. Thus, the electrostatic carrier 100 may be disposed on a carrier-holding platform 140 without becoming chucked to the carrier-holding platform 140. The floating electrode 130 has a hole 132 through which electrode 120A is electrically connected to the contact pad 116. The floating electrode 130 has another hole 134 through which electrode 120B is electrically connected to the contact pad 118.

A carrier-holding platform 140 is configured to charge the electrostatic carrier 100. The carrier-holding platform 140 includes a power source 145 and two pogo pins 142 and 144 connected to the power source 145. The pogo pin 142 is configured to deliver AC or DC electrical power to the electrode 120A, when the pogo pin 142 is in contact with the contact pad 116. The pogo pin 144 is configured to deliver AC or DC electrical power to the electrode 120B, when the pogo pin 144 is in contact with the contact pad 118. The power source 145 is thus configured to provide electrical power to the electrodes 120A and 120B to generate charges with opposite polarity. In one embodiment, the power source 145 may be configured to provide +/−0.5-3 kV DC power to the electrodes 120A and 120B. In an alternative embodiment, a battery power source (not shown) may be embedded within the electrostatic carrier 100 to charge the electrodes 120A and 120B. The positive and negative charge applied on the electrodes 120A and 120B generate an electrostatic force on the top surface 112 that attracts and secures a plurality of dies to the electrostatic carrier 100.

The arrangement of electrodes 120A, 120B on the electrostatic carrier 100 can be configured in many different ways. For example, FIG. 2 shows a top view of one embodiment of the electrostatic carrier 100 of FIG. 1. In FIG. 2, the electrostatic carrier 200 has electrodes 220A and 220B disposed under the top surface 212. The electrode 220A has a terminal 222A and a plurality of electrode fingers 224A. The electrode 220B has a terminal 222B and a plurality of electrode fingers 224B. The plurality of electrode fingers 224A, 224B interleave with each other to provide local electrostatic attraction distributed across a large area of the top surface 212 which, in aggregate, provides a high chucking force while using less electrical power. The electrode fingers 224A, 224B may be formed with different lengths and geometry. Between each of the electrode fingers 224A of the electrode 220A, spaces 225 are defined to receive the electrode fingers 224B of the electrode 220B. The spaces 225 may be an air gap or filled with a dielectric spacer material.

FIG. 3 and FIG. 4 show the top views of other embodiments of the electrostatic carrier 100 of FIG. 1. For example, FIG. 3 shows an electrostatic carrier 300 having concentric electrodes 320A and 320B of opposite polarity. The electrode 320A has the electrode terminals 322A. The electrode 320B has the electrode terminals 322B. FIG. 4 shows an electrostatic carrier 400 having semi-circular electrodes 420A and 420B of opposite polarity. The electrode 420A has the electrode terminal 422A. The electrode 420B has the electrode terminal 422B.

FIG. 5 shows the top view of another embodiment of the electrostatic carrier 100 of FIG. 1. FIG. 5 shows an electrostatic carrier 500 having a plurality of inter-digitated bipolar chucking electrodes 520. Each bipolar chucking electrode 520 has two electrodes 520A and 520B of opposite polarity. The electrode 520A has the electrode terminals 522A. The electrode 520B has the electrode terminals 522B. Each bipolar chucking electrode 520 is configured to electrostatically attract and secure one die 580 on the top surface 512 of the electrostatic carrier 500. Thus, one or more dies 580 can be chucked to the top surface 512 of the electrostatic carrier 500.

FIG. 6 is an electrical schematic view of one embodiment of the electrostatic carrier 100. In FIG. 6, a first bipolar chucking electrode 120 has electrodes 120A and 120B. The electrode 120A is electrically connected to the contact pad 116 by a switch 125. The electrode 120B is electrically connected to the contact pad 118 by the switch 125. Similarly, a second bipolar chucking electrode 120′ has electrodes 120A′ and 120B′. The electrode 120A′ is electrically connected to the contact pad 116′ by a switch 125′. The electrode 120B′ is electrically connected to the contact pad 118′ by the switch 125′. Open and closed states of the switches 125 and 125′ are controlled by a controller 615, which may be located inside or outside the electrostatic carrier 100. The controller 615 is configured to control the second bipolar chucking electrode 120′ independently relative to the first bipolar chucking electrode 120 by independently controlling the states of the switches 125, 125′.

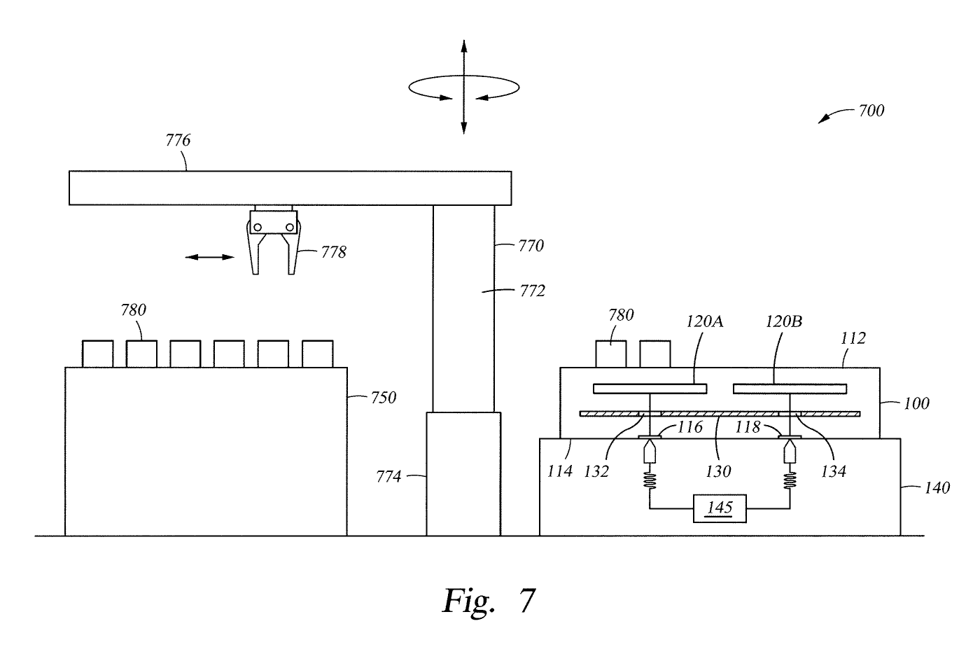

FIG. 7 is a simplified front cross-sectional view of a die-assembling system 700 for loading a plurality of dies on the electrostatic carrier 100. The die-assembling system 700 includes the electrostatic carrier 100 configured to electrostatically secure the plurality of dies, as described above.

The electrostatic carrier 100 is placed on the carrier-holding platform 140. The carrier-holding platform 140 has a power source 145 and two pogo-pins 142 and 144 electrically connected to the power source 145. The pogo-pins 142, 144 are configured to connect with the contact pads 116, 118 and provide electrical power from the power source 145 to the electrodes 120A, 120B. The power source 145 is thus configured to provide electrical power to the electrodes 120A, 120B to generate charges with opposite polarity.

The die-assembling system 700 includes a die input platform 750 having a plurality of dies 780 disposed thereon. The die input platform 750 is located proximate to the electrostatic carrier 100 on the carrier-holding platform 140. A loading robot 770 is also located proximate to the die input platform 750 and the electrostatic carrier 100. The loading robot 770 has a body 772 connected to an arm 776. The body 772 is coupled to an actuator 774. The actuator 774 is configured to move the arm up and down in a vertical direction as well as laterally in a horizontal direction. The actuator 774 is also configured to rotate the arm 776 about a vertical axis disposed through the body 772 such that the arm 776 can move between a position above the die input platform 750 and a position above the electrostatic carrier 100. The arm 776 includes a gripper 778 configured to pick the plurality of dies 780 disposed on the die input platform 750 and place the plurality of dies 780 on the electrostatic carrier 100. The gripper 778 is operated by an actuator (not shown). In some embodiments, the gripper 778 may be a mechanical gripper, though in other embodiments, the gripper 778 may be a vacuum chuck, an electrostatic chuck, or other suitable die holder. The plurality of dies 780 is placed on the electrostatic carrier 100 and electrostatically secured thereto for transportation through a number of subsequent cleaning operations.

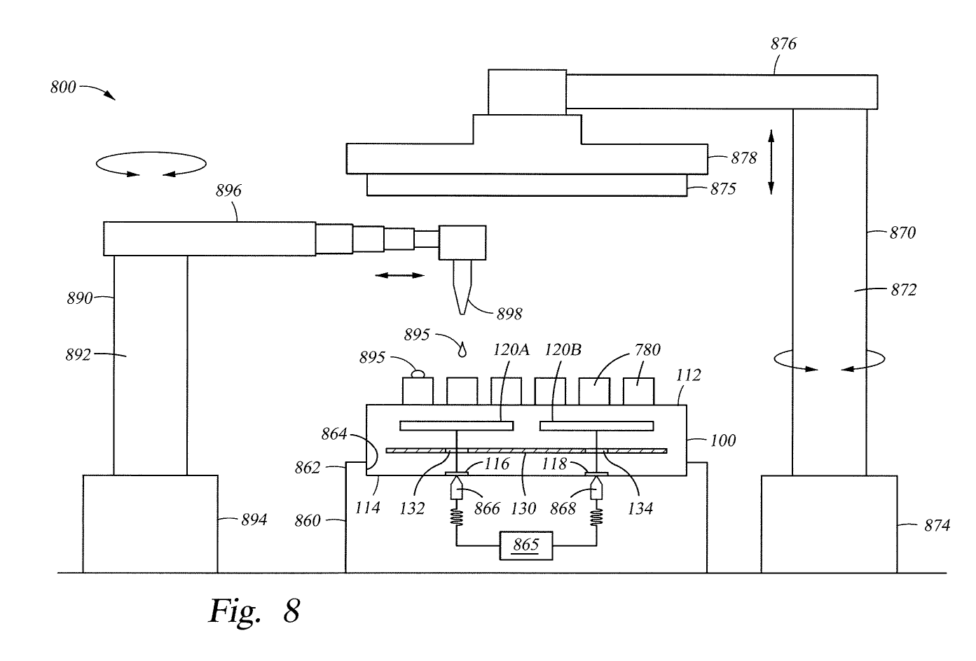

FIG. 8 is a simplified front cross-sectional view of a die-assembling system 800 for assembling the plurality of dies 780 disposed on the electrostatic carrier 100 with a substrate 875 after the cleaning operations. The die-assembling system 800 includes a carrier-holding platform 860 configured to receive the electrostatic carrier 100. As discussed above, the electrostatic carrier 100 has the plurality of dies 780 electrostatically secured thereon. The carrier-holding platform 860 has a wall 862 that defines a pocket 864 for holding the electrostatic carrier 100. The diameter of the pocket 864 is greater than the diameter of the electrostatic carrier 100 so that the electrostatic carrier 100 can be positioned within the pocket 864. The carrier-holding platform 860 also includes a power source 865 and two pogo pins 866, 868 electrically connected to the power source 865. The pogo pins 866, 868 are configured to deliver AC or DC electrical power to the electrodes 120A, 120B, when the pogo pins 866, 868 contact with the contact pads 116, 118.

A first robot 870 is located proximate to the electrostatic carrier 100. The first robot 870 has a body 872 connected to an arm 876. The arm 876 is coupled to a gripper 878. The gripper 878 is configured to hold the substrate 875 above the electrostatic carrier 100. The gripper 878 is operated by an actuator (not shown). In some embodiments, the gripper 878 may be a mechanical gripper for holding the substrate 875. However, in other embodiments, the gripper 878 may be a vacuum chuck, an electrostatic chuck, or other suitable substrate holder for holding the substrate 875. The body 872 of the first robot 870 is coupled to an actuator 874. The actuator 874 is configured to move the gripper 878 up and down such that the substrate 875 moves towards and away from the plurality of dies 780 that is electrostatically chucked to the electrostatic carrier 100 on the carrier-holding platform 860.

The substrate 875 may be a CMOS wafer, though in other embodiments, it may be any semiconductor substrate ready to have dies assembled thereon. The substrate 875 may be composed of one or more of a variety of different materials, such as but not limited to silicon, gallium arsenide, lithium niobate, etc. The substrate 875 may have a diameter of 200 mm, 300 mm, 450 mm or other diameter.

A second robot 890 is located proximate to the electrostatic carrier 100 in the die-assembling system 860. The second robot 890 has a body 892 and an arm 896. The arm 896 is coupled to a dispenser 898. The dispenser 898 is configured to dispense a liquid 895 on the plurality of dies 780 that are electrostatically chucked to the electrostatic carrier 100. In some embodiments, the liquid 895 is about a nanoliter of water, though in other embodiments, a similar measure of water or another liquid may be used. The body 892 of the second robot 890 is coupled to an actuator 894. The actuator 894 is configured to move the arm 896 laterally in a horizontal direction as well as rotate the arm 896 about a vertical axis through the body 892 such that the arm 896 can move towards and away from a position above the electrostatic carrier 100. The rotational and translational movement of the arm 896 selectively positions the dispenser 898 over each die 780 so that the dispenser 898 may apply the liquid 895 on top of each die 780 disposed on the electrostatic carrier 100, while positioned in the die-assembling system 860.

In some embodiments, the electrostatic carrier 100, the die input platform 750 and the loading robot 770 are part of the die-assembling system 800, thus forming embodiments of a die-assembling system (not shown) where the dies 780 can be picked from the die input platform 750, placed on the electrostatic carrier 100 by the loading robot 770 and then transported to the carrier-holding platform 860 for subsequent assembly on the substrate 875.

The electrostatic carrier 100 and the die-assembling systems 700 and 800 described herein, advantageously enable a plurality of dies of different types and sizes to be electrostatically secured and transported through cleaning operations and on to a die-assembling system for subsequent assembly on a substrate. During operation of the electrostatic carrier 100, electrical power is applied to the bipolar chucking electrode 120 when the contact pads 116, 118 are placed in contact with the pogo pins 142, 144 of the carrier-holding platform 140. When power is applied from the power source 145 through the pogo pins 142, 144, a negative charge may be applied to the electrode 120A and a positive charge may be applied to the electrode 120B, or vice-versa, to generate an electrostatic force. During chucking, the electrostatic force generated from the electrodes 120A, 120B attracts and secures the plurality of dies 780 to the electrostatic carrier 100. Subsequently, when the power supplied by the power source 145 is disconnected, the residual charges on the bipolar chucking electrode 120 is sufficiently maintained over a period of time such that the plurality of dies 780 can be electrostatically secured and freely transported between the die-assembling systems 700 and 800, without reconnection to another power source. To de-chuck the plurality of dies 780 from the electrostatic carrier 100, a short pulse of power in the opposite polarity may be provided to the electrodes 120A, 120B or the electrodes 120A, 120B may be shorted utilizing internal switches (not shown). As a result, the residual charges present in the bipolar chucking electrode 120 are removed, thus freeing the dies 780.

In the die-assembling system 700, the electrostatic carrier 100 is placed on the carrier-holding platform 140, where the electrostatic carrier 100 may be electrostatically charged. The carrier-holding platform 140 is proximate to a loading robot 770 and a die input platform 750 having the plurality of dies 780 disposed thereon. The loading robot 770 is utilized to pick the plurality of dies 780 from the die input platform 750 and place them on the electrostatic carrier 100. The actuator 774 of the loading robot 770 moves the arm 776 vertically and horizontally, and rotates the arm about a vertical axis through the body 772 of the loading robot 770. The translational and rotational movement of the arm 776 positions a gripper 778 coupled to the arm 776 to enable the gripper 778 to pick the dies 780 from the die input platform 750 and place the dies 780 on the electrostatic carrier 100. The plurality of dies 780 is then chucked to the electrostatic carrier 100. The electrostatic carrier 100 may be charged before or after the plurality of dies 780 is placed thereon. The plurality of dies 780 thus secured to the electrostatic carrier 100 is transported through cleaning operations such as immersion in a cleaning bath, brush cleaning, megasonic cleaning, etc.

In the die-assembling system 800, the electrostatic carrier 100 with the plurality of dies 780 is placed on a carrier-holding platform 860. The carrier-holding platform 860 is proximate to a first robot 870 and a second robot 890. A substrate 875 is moved by a robot 870 into a position above the electrostatic carrier 100 held in the carrier-holding platform 860 in order to assemble the plurality of dies 780 on the substrate 875. The second robot 890 is utilized to dispense a liquid 895 on the plurality of dies 780. The second robot 890 positions the arm 896 horizontally and rotates the arm 896 about a vertical axis through the body 892 of the second robot 890 such that the arm 896 can move towards and away from a position above the electrostatic carrier 100. The rotational and translational movement of the arm 896 selectively positions the dispenser 898 over each die 780. The dispenser 898 dispenses the liquid 895, such as a droplet, on top of each of the plurality of dies 780 chucked to the electrostatic carrier 100.

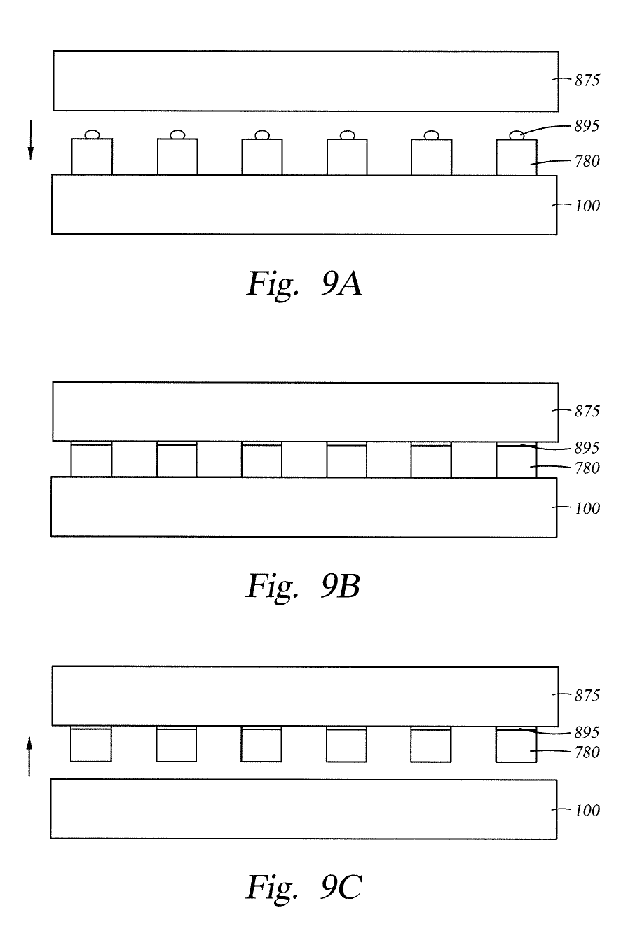

As shown in FIG. 9A, the substrate 875 is then moved by the first robot 870 towards the plurality of dies 780. The first robot 870 moves the gripper 878 on the arm 876 down such that the substrate 875 attached to the gripper 878 can contact the liquid 895 dispensed on the plurality of dies 780 disposed on the electrostatic carrier 100. The plurality of dies 780 is de-chucked from the electrostatic carrier 100, for example by applying a voltage of reverse polarity from the power source 865 on the carrier-holding platform 860. As shown in FIG. 9B, the plurality of dies 780 lay unsecured on the electrostatic carrier 100 when the substrate 875 engages with the plurality of dies 780. The liquid 895 creates a force due to surface tension between the substrate 875 and the de-chucked dies 780 such that the plurality of dies 780 self-aligns and attaches to the substrate 875. When the plurality of dies 780 is secured to the substrate 875, the first robot 870 moves the gripper 878 away from the electrostatic carrier 100, as shown in FIG. 9C. The plurality of dies 780, thus assembled on the substrate 875, is transferred for permanent bonding and other processes.

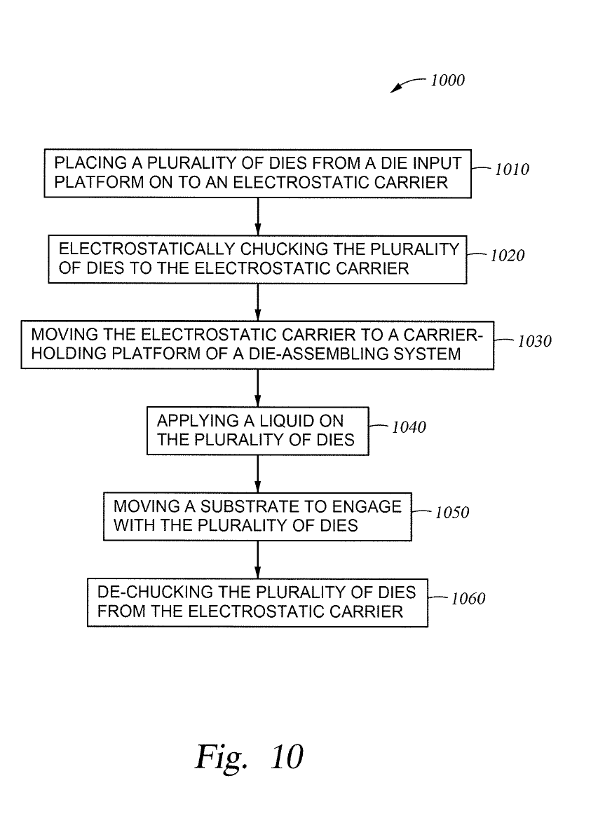

FIG. 10 is a block diagram of a method 1000 of assembling a plurality of dies on a substrate using an electrostatic carrier, according to another embodiment of the present disclosure. The method 1000 begins at block 1010 by placing the plurality of dies from a die input platform on to an electrostatic carrier. The electrostatic carrier has at least one bipolar chucking electrode having two electrodes. When power is applied to the bipolar chucking electrode, the electrodes acquire charges of opposite polarity, thus generating an attractive electrostatic force.

At block 1020, the plurality of dies is electrostatically chucked to the electrostatic carrier. The plurality of dies is secured by electrostatic force from the bipolar chucking electrode disposed in the electrostatic carrier. In some embodiments, the electrostatic carrier may be charged before the plurality of dies is placed thereon. In other embodiments, the electrostatic carrier is charged after the plurality of dies is placed thereon. In either case, the plurality of dies is secured to the electrostatic carrier and can be freely transported without need for permanent connection to a power source. The plurality of dies is thus transported through cleaning operations such as immersion in a cleaning bath, brush cleaning, megasonic cleaning, etc.

At block 1030, the electrostatic carrier is moved to a carrier-holding platform of a die-assembling system. The cleaned dies remain electrostatically chucked to the electrostatic carrier upon arrival at the die-assembling system. Upon arrival, the electrostatic carrier is positioned below a substrate held by a first robot in order to assemble the cleaned dies to the substrate.

At block 1040, a liquid is applied on the plurality of dies by a dispenser attached to a second robot. In some embodiments, the liquid is about a nanoliter of water, though in other embodiments a similar measure of water or another liquid may be used.

At block 1050, the substrate is moved down by the first robot towards the plurality of dies to pick the plurality of dies from the electrostatic carrier. As the substrate approaches the plurality of dies, the substrate touches the surface of the liquid applied on the plurality of dies. The operation of block 1050 may occur before, after or at the same time as the operation of block 1060.

At block 1060, the plurality of dies is de-chucked from the electrostatic carrier. De-chucking is the process of substantially removing the electrostatic charge that holds the plurality of dies to the electrostatic carrier by applying a voltage of reverse polarities to or shorting the electrodes disposed in the electrostatic carrier. The reduction or absence of electrostatic force causes the plurality of dies to be de-chucked from the electrostatic carrier. After de-chucking, the plurality of dies lay unsecured on the electrostatic carrier and is free to be transferred to the substrate.

The liquid applied on the plurality of dies creates a force due to surface tension as the substrate touches the liquid disposed on the plurality of dies. The force of surface tension pulls the plurality of dies from the electrostatic carrier on to the bottom surface of the substrate. Once the plurality of dies is secured to the bottom surface of the substrate by the force of surface tension, the substrate is moved away from the electrostatic carrier by the first robot.

The electrostatic carrier described herein is used to secure and transport a plurality of dies through cleaning operations and on to a die-assembling system, where the plurality of dies is assembled on a substrate. The ability to secure and transport dies in bulk offers a considerable advantage over the individual transfer of dies from a tape frame to a die-holder and on to a substrate, as is currently used. The time required for transferring the dies on to the substrate is considerably reduced and hence throughput of assembled dies is increased. Moreover, the electrostatic carrier described herein can accommodate multiple die types and sizes, thus offering another advantage over the existing die-holder which is pre-made for a specific die size.

While the foregoing is directed to particular embodiments of the present disclosure, it is to be understood that these embodiments are merely illustrative of the principles and applications of the present invention. It is therefore to be understood that numerous modifications may be made to the illustrative embodiments to arrive at other embodiments without departing from the spirit and scope of the present inventions, as defined by the appended claims.

What is claimed is:

1. An electrostatic carrier comprising:
a body having a top surface and a bottom surface;
at least a first bipolar chucking electrode disposed within the body;
at least two contact pads disposed on the bottom surface of the body and connected to the first bipolar chucking electrode; and
a floating electrode disposed between the first bipolar chucking electrode and the bottom surface.

2. The electrostatic carrier of claim 1, further comprising:
a second bipolar chucking electrode disposed within the body, the second bipolar chucking electrode independently controllable relative to the first bipolar chucking electrode.

3. The electrostatic carrier of claim 1, wherein the body has three or more layers.

4. The electrostatic carrier of claim 3, wherein the body further comprises:
a dielectric top layer disposed on top of a core layer wherein the first bipolar chucking electrode is disposed therein; and
a dielectric bottom layer disposed below the core layer wherein the floating electrode is disposed therein.

5. The electrostatic carrier of claim 4, wherein the dielectric top layer and the dielectric bottom layer are formed from a silicon based ceramic material and the core layer is formed from an aluminum based ceramic material.

6. The electrostatic carrier of claim 4, further comprising:
a top hydrophobic layer on the dielectric top layer and a bottom hydrophobic layer disposed below the dielectric bottom layer.

7. A die-assembling system, comprising:
an electrostatic carrier configured to electrostatically secure a plurality of dies, the electrostatic carrier comprising:
a body having a top surface and a bottom surface;
at least a first bipolar chucking electrode disposed within the body;
at least two contact pads disposed on the bottom surface of the body and connected to the first bipolar chucking electrode; and
a floating electrode disposed between the first bipolar chucking electrode and the bottom surface;
a carrier-holding platform configured to hold the electrostatic carrier;
a die input platform; and
a loading robot having a range of motion configured to pick the plurality of dies from the die input platform and place them on the electrostatic carrier.

8. The die-assembling system of claim 7 wherein the electrostatic carrier further comprises:
a second bipolar chucking electrode disposed within the body, the second bipolar chucking electrode independently controllable relative to the first bipolar chucking electrode.

9. The die-assembling system of claim 7 wherein the electrostatic carrier further comprises:
a hydrophobic coating disposed on the top surface and the bottom surface of the body.

10. The die-assembling system of claim 7, wherein the body of the electrostatic carrier has three or more layers.

11. The die-assembling system of claim 10, wherein the body of the electrostatic carrier further comprises:
a dielectric top layer disposed on top of a core layer wherein the first bipolar chucking electrode is disposed therein; and
a dielectric bottom layer disposed below the core layer wherein the floating electrode is disposed therein.

12. The die-assembling system of claim 11, further comprising:
a top hydrophobic layer on the dielectric top layer and a bottom hydrophobic layer disposed below the dielectric bottom layer.

13. The die-assembling system of claim 11, wherein the dielectric top layer and the dielectric bottom layer are formed from a silicon based ceramic material.

14. The die-assembling system of claim 13, wherein the core layer is formed from an aluminum based ceramic material.

15. The die-assembling system of claim 7 further comprising:
a second carrier-holding platform configured to receive the electrostatic carrier;
a first robot configured to move a substrate towards and away from the plurality of dies electrostatically chucked to the electrostatic carrier disposed in the second carrier-holding platform; and
a second robot configured to dispense a liquid on the plurality of dies.

16. The die-assembling system of claim 7, wherein the electrostatic carrier holding platform further comprising:
at least two pins configured to deliver electrical power to the first bipolar chucking electrode when the pin is in contact with the contact pads.

17. A method of assembling a plurality of dies on a substrate, the method comprising:
placing the plurality of dies from a die input platform on to an electrostatic carrier;
electrostatically chucking the plurality of dies to the electrostatic carrier;
moving the electrostatic carrier to a carrier-holding platform of a die-assembling system;
applying a liquid on the plurality of dies;
moving a substrate to engage with the plurality of dies; and
de-chucking the plurality of dies from the electrostatic carrier.

18. The method of claim 17 further comprising:
pre-charging the electrostatic carrier on a carrier holding platform prior to placing the plurality of dies thereon.

19. The method of claim 17 wherein the electrostatic carrier is charged after the plurality of dies are placed thereon.

20. The method of claim 17 wherein the substrate engages with the plurality of dies is electrostatically chucked to a second carrier.
